(19) United States
(12) Patent Application Publication
(10) Pub. No.: US 2016/0116612 A1
(43) Pub. Date: Apr. 28, 2016

(54) RADIATION DETECTION APPARATUS AND METHOD OF DRIVING THE SAME

(71) Applicant: SAMSUNG ELECTRONICS CO., LTD., Suwon-si (KR)

(72) Inventors: Kangho LEE, Osan-si (KR); Jinmyoung KIM, Hwaseong-si (KR); Jaechul PARK, Yangju-si (KR)

(21) Appl. No.: 14/807,192

(22) Filed: Jul. 23, 2015

(30) Foreign Application Priority Data
Oct. 22, 2014 (KR) 10-2014-0143599

(51) Int. Cl. G01T 1/24; G01N 23/04

(52) U.S. Cl. CPC G01T 1/247; G01N 23/04; G01T 1/241

(57) ABSTRACT

Disclosed is a method of driving a radiation detection apparatus using a variable voltage applying scheme. In the method, different voltages are applied in a standby step, where radiation is not irradiated onto the radiation detection apparatus, and an irradiation step where the radiation is irradiated. A voltage which is applied in the standby step has an absolute value lower than a voltage which is applied in the irradiation step, and is set to minimize a dark current which is generated in a photoconductor layer of the radiation detection apparatus in the standby step.

### RELATED APPLICATION

This application claims the benefit of Korean Patent Application No. 10-2014-0143599, filed on Oct. 22, 2014, in the Korean Intellectual Property Office, the disclosure of which is incorporated herein in its entirety by reference.

### BACKGROUND

1. Field

Example embodiments relate to a radiation detection apparatus and/or a method of driving the same.

2. Description of the Related Art

Radiation, such as X-rays or gamma rays (y-ray), has strong transmissivity, and thus, can be used to visualize the inside of an object. Therefore, radiation is generally used in medical areas and for nondestructive inspection. A radiation transmission amount changes with the density of the inside of an object, and the inside of the object is imaged by measuring a difference between radiation transmission amounts.

A photoconductor (i.e., an optical-to-electric conversion material) may be used for detecting the difference between radiation transmission amounts. When a photoconductor is irradiated, electron-hole pairs may be generated in the photoconductor, and thus, when an electric field is generated in the photoconductor, the electron-hole pairs may be separated into electrons and holes that may be converted into an electrical signal. An amount of electric charges generated in a photoconductor may change with an amount (intensity) of radiation passing through an object and reaching a photoconductor. Thus, the inside of the object may be imaged based on the difference between the amounts of electric charges generated.

### SUMMARY

Example embodiments relate to a radiation detection apparatus and/or a method of driving the same.

Additional aspects will be set forth in part in the description which follows and, in part, will be apparent from the description, or may be learned by practice of the presented example embodiments.

Some example embodiments relate to a method of driving a radiation detection apparatus which includes a plurality of pixel electrodes, a counter electrode that faces the plurality of pixel electrodes, and a photoconductor layer that is disposed between the plurality of pixel electrodes and the counter electrode.

In some example embodiments, the method includes: a standby step of applying a first voltage to the counter electrode when no radiation is irradiated to the photoconductor layer; and a irradiation step of applying a second voltage, having an absolute value greater than that of the first voltage, to the counter electrode and irradiating radiation to the photoconductor layer.

The first voltage may be 0 V or a floating voltage.

A value of the first voltage may be set so that the plurality of pixel electrodes and the counter electrode have a substantially equivalent electric potential.

The radiation detection apparatus may further include a readout circuit unit that is connected to the plurality of pixel electrodes, and the first voltage may be substantially equivalent to a reference common voltage of the readout circuit unit.

An absolute value of the second voltage may be 300 V or less.

The radiation detection apparatus may further include a capacitor that is connected to each of the plurality of pixel electrodes, a transistor that switches the capacitor, and a readout circuit unit that is connected to the transistor, and the method may further include, between the applying of the first voltage and the applying of the second voltage, discharging an electric charge charged into the capacitor.

The applying of the second voltage may include collecting electric charges, generated by the radiation irradiated onto the photoconductor layer, in the capacitor connected to each of the plurality of pixel electrodes.

The method may further include sequentially discharging the capacitor so that the electric charge stored in the capacitor is read by the readout circuit unit.

Other example embodiments relate to a radiation detection apparatus.

In some example embodiments, the relation detection apparatus may include a substrate in which a plurality of pixel electrodes are arranged; a counter electrode that faces the plurality of pixel electrodes; a photoconductor layer that is disposed between the plurality of pixel electrodes and the counter electrode, and generates an electric charge by reacting on radiation; a voltage source that applies a variable voltage to the counter electrode; and a control unit that applies a first voltage to the counter electrode in a state where the radiation is not irradiated onto the photoconductor layer, and applies a second voltage, having an absolute value greater than the first voltage, to the counter electrode in a state where the radiation is irradiated onto the photoconductor layer.

The control unit may set the first voltage to 0 V or a floating voltage.

The control unit may set a value of the first voltage so that the plurality of pixel electrodes and the counter electrode have a substantially equivalent electric potential.

The radiation detection apparatus may further include: a plurality of capacitors that are respectively connected to the plurality of pixel electrodes; a plurality of transistors that respectively switch the plurality of capacitors; and a readout circuit unit that is connected to the plurality of transistors.

The control unit may set the first voltage to be substantially equivalent to a reference common voltage of the readout circuit unit.

The photoconductor layer may include HgI₂, HgO, PbI₂, CdTe, CdZnTe, PbO, PbO₂, CdS, or BiI₃.

The control unit may set an absolute value of the second voltage to 300 V or less.

The radiation detection apparatus may be an X-ray detector or a gamma ray (γ-ray) detector.

Other example embodiments relate to a radiation imaging apparatus.

In some example embodiments, the radiation imaging apparatus may include a radiation generating unit that irradiates radiation onto an object; a radiation detection unit that outputs an electrical signal by using the radiation passing through the object, and includes a plurality of pixel electrodes, a counter electrode that faces the plurality of pixel electrodes, and a photoconductor layer that is disposed between the plurality of pixel electrodes and the counter electrode; a voltage source that applies a variable voltage to the counter electrode; and a control unit that controls the voltage source to apply a first voltage to the counter electrode in a state where the radiation is not irradiated onto the photoconductor layer and apply a second voltage, having an absolute value greater than the first voltage, to the counter electrode in a state where the radiation is irradiated onto the photoconductor layer.

Some example embodiments relate to a method of reducing a dark current output by a photoconductive material.

In some example embodiments, the method may include applying a first voltage to the photoconductor such that an electrostatic field is not formed therein during a standby operation; and applying a second voltage to the photoconductive material to form the electrostatic field during a collection operation in which x-rays are irradiated onto the photoconductive material after the standby operation, an absolute value of the second voltage being greater than an absolute value of the first voltage.

### BRIEF DESCRIPTION OF THE DRAWINGS

These and/or other aspects will become apparent and more readily appreciated from the following description of the example embodiments, taken in conjunction with the accompanying drawings in which:

FIG. 1 is a cross-sectional view illustrating a schematic structure of a radiation detection apparatus according to an example embodiment;

FIG. 2 is a flowchart for describing a method of driving a radiation detection apparatus according to an example embodiment;

FIGS. 3A to 3C are diagrams illustrating examples in which a voltage is applied to a counter electrode of a radiation detection apparatus in a standby step of the flowchart of FIG. 2;

FIG. 4 is a diagram for describing an operation in which a second voltage is applied to the counter electrode of the radiation detection apparatus, and when radiation is irradiated onto a photoconductor layer, a photocurrent is generated by the radiation, in an irradiation step of the flowchart of FIG. 2;

FIG. 5 is a schematic diagram illustrating a transistor and a charging capacitor, which are formed on an array substrate of a radiation detection apparatus according to an example embodiment, for one pixel;

FIG. 6 is a circuit diagram illustrating an example of a circuit configuration of a radiation detection apparatus according to an example embodiment;

FIG. 7 is a block diagram illustrating in detail driving of radiation, a variable voltage source, a gate, and a charging capacitor in each step of a method of driving a radiation detection apparatus according to an example embodiment;

FIG. 8 is a graph showing driving of radiation, an application voltage, and a gate with time in each step of a method of driving a radiation detection apparatus according to an example embodiment;

FIG. 9 is a graph showing a change in a capacitor voltage in each step of a method of driving a radiation detection apparatus according to an example embodiment;

FIG. 10 is a flowchart for describing a method of driving a radiation detection apparatus according to a comparative example;

FIGS. 11A and 11B are conceptual diagrams for describing an operation in which an electric charge caused by a dark current is detected along with an electric charge caused by radiation, in a method of driving a radiation detection apparatus according to a comparative example;

FIG. 12 is a graph showing driving of radiation, an application voltage, and a gate with time in each step of a method of driving a radiation detection apparatus according to a comparative example;

FIG. 13 is a graph showing a change in a capacitor voltage in each step of a method of driving a radiation detection apparatus according to an example embodiment; and

FIG. 14 is a block diagram illustrating a schematic configuration of a radiation imaging apparatus according to an example embodiment.

### DETAILED DESCRIPTION

Reference will now be made in detail to example embodiments, some examples of which are illustrated in the accompanying drawings, wherein like reference numerals refer to like elements throughout. In this regard, the example embodiments may have different forms and should not be construed as being limited to the descriptions set forth herein. Accordingly, the example embodiments are merely described below, by referring to the figures, to explain aspects.

Hereinafter, example embodiments will be described in detail with reference to the accompanying drawings. The example embodiments should not be construed as being limited to the example embodiments set forth herein; rather, these embodiments are provided so that this disclosure will be thorough and complete, and will fully convey the example embodiments of the inventive concepts to those of ordinary skill in the art. In the drawings, like reference numerals refer to like elements, and the size and thickness of each element may be exaggerated for clarity and convenience of description.

It will be understood that although the terms “first”, “second”, etc. may be used herein to describe various components, these components should not be limited by these terms. These components are only used to distinguish one component from another.

Moreover, each of terms such as “. . . unit”, “. . . apparatus” and “module” described in specification denotes an element for performing at least one function or operation, and may be implemented in hardware, software or the combination of hardware and software.

The expressions “about”, “substantially”, “equivalent”, “more than”, and “less than” described in association with a numerical value in the present specification should not be construed as matching a corresponding expression when the corresponding expression completely matches a described numerical value. The expressions are within a range which is commonly accepted by one of ordinary skill in the art, and for example, may include a range which is accepted by a relevant measurement error and a limitation of a measurement system.

The term “radiation image” used herein denotes an image of an object acquired by using radiation. Also, the term “object” used herein may include a person, an animal, a part of the person, or a part of the animal. For example, an object may include an organ such as a liver, a heart, a womb, a brain, breasts, an abdomen, or the like, or a blood vessel. Moreover, the term “user” used herein is a medical expert, and may be a doctor, a nurse, a medical technologist, a medical image expert, or the like, or may be an engineer who repairs a medical apparatus. However, the user is not limited thereto.

FIG. 1 is a cross-sectional view illustrating a schematic structure of a radiation detection apparatus 100 according to an example embodiment.

Referring to FIG. 1, the radiation detection apparatus 100 includes an array substrate 110 in which a plurality of pixel electrodes PE are formed, a counter electrode CE that faces the plurality of pixel electrodes PE, and a photoconductor layer 130 that is disposed between the plurality of pixel electrodes PE and the counter electrode CE. The radiation detection apparatus 100 further includes a variable voltage source 150 that applies a variable voltage to the counter electrode CE.

The plurality of pixel electrodes PE may be formed on the array substrate 110 in a two-dimensional (2D) array. A charging capacitor and a transistor, which are respectively connected to the plurality of pixel electrodes PE, may be further formed on the array substrate 110.

The counter electrode CE may be disposed to face the plurality of pixel electrodes PE. The counter electrode CE may be an electrode for generating an electric field in the photoconductor layer 130, and may be referred to as a common electrode in a sense of applying a common voltage having a polarity opposite to each of the plurality of pixel electrode PE.

The photoconductor layer 130 may be formed of an optical-to-electric conversion material that has conductivity due to light. The optical-to-electric conversion material is a material that has properties of a dielectric when light is not irradiated, but has properties of a conductor when light is irradiated. In an example embodiment, as an example of the optical-to-electric conversion material, a material that has a characteristic of generating an electric charge by reacting to radiation such as an X-ray or a gamma ray (γ-ray) may be used for the photoconductor layer 130. That is, the radiation detection apparatus 100 according to an example embodiment may be an X-ray detector or a gamma ray (γ-ray) detector.

When radiation is irradiated onto the photoconductor layer 130, an electron may be excited to a conduction band by energy of the irradiated radiation. In a state where an electric field is not generated in the photoconductor layer 130, electrons excited by radiation are again shifted to a ground state and form a valence band. When radiation is irradiated in a state where an electric field is generated in the photoconductor layer 130, electric charges that form the conduction band due to radiation energy move along a direction of the electric field. The moved electric charges may be collected, and may be used to generate a radiation image.

The photoconductor layer 130 may be formed of various kinds of photoconductive materials. The photoconductor layer 130 may include, for example, HgI₂, HgO, PbI₂, CdTe, CdZnTe, PbO, PbO₂, CdS, or BiI₃. The materials may absorb radiation (an X-ray or a gamma ray) well in a thin thickness because the atomic weight of the materials is large and a density of the materials is high, and since ionization energy caused by radiation is small, the materials may show good photoconductive performance. Since the materials may show good photoconductive performance, the conversion efficiency of absorbing radiation and generating an electron-hole pairs may be high. That is, the good photoconductive performance denotes that since quantum efficiency is high, the number of electron-hole pairs generated by irradiated radiation is large.

As conversion efficiency becomes lower, a thickness of the photoconductor layer 130 may be thicker to obtain a desired electrical signal. Since a distance by which an electric charge is moved in the photoconductor layer 130 is long for collecting electric charges generated by radiation, a higher electric field is generated in a case, where the thickness of the photoconductor layer 130 is thick, than a case where the thickness of the photoconductor layer 130 is thin. Therefore, when an optical-to-electric conversion material having high conversion efficiency is used for the photoconductor material 130, the thickness of the photoconductor layer 130 may be relatively thin, and electric charges may be collected with a relatively lower bias voltage.

For example, in amorphous selenium (a-Se), a bias voltage of several KV to several tens KV may be needed for detection an electric charge reacting on radiation. On the other hand, in mercury iodide HgI₂, an electric charge caused by radiation may be detected by using a bias voltage of several hundreds V, for example, a bias voltage of about 300 V or less.

The photoconductor layer 130 may be formed by a particle-in-binder (FIB) process. According to the PIB process, the photoconductor layer 130 is formed by performing thermal treatment on a paste in which photoconductive particles are mixed with a binder. The photoconductive particles are materials having optical-to-electric conversion characteristic, and may include HgI₂, HgO, PbI₂, CdTe, CdZnTe, PbO, PbO₂, CdS, or BiI₃. The binder is a material that is mixed with the photoconductive particles to apply an adhesive force, and may use an organic polymer material.

The PIB process is known as a process of thickly forming the photoconductor layer 130 to have a large area. However, a process of forming the photoconductor layer 130 is not limited thereto, and the photoconductor layer 130 may be formed by a physical vapor deposition (PVD) process. That is, the photoconductor layer 130 may be formed by a process that evaporates a target, formed of one or two or more compounds of the optical-to-electric conversion materials, by applying a physical force to the target.

The variable voltage source 150 applies a voltage to the counter electrode CE to generate an electric field in the photoconductor layer 130. In some example embodiments, the variable voltage source 150 applies different voltages to the counter electrode CE depending on an operation performed by the radiation detection apparatus 100.

For example, the variable voltage source 150 may apply different voltages to the counter electrode CE in a standby operation where radiation is not irradiated onto the photoconductor layer 130 and in an irradiation operation where the radiation is irradiated onto the photoconductor layer 130.

Hereinafter, the voltage that is applied to the counter electrode CE in the standby operation is referred to as a first voltage, and the voltage that is applied to the counter electrode CE in the irradiation operation is referred to as a second voltage.

The first voltage is a voltage that is applied to the counter electrode CE so that an electric field is not generated (or, alternatively, reduced or minimized) in the photoconductor layer 130, and the second voltage is a voltage for generating an electric field, which moves an electric charge that is generated by radiation to the pixel electrodes PE, in the photoconductor layer 130. The second voltage may have an absolute value greater than the first voltage, and a value of the second voltage may be determined based on a material forming the photoconductor layer 130. For example, in HgI₂, the second voltage may be a value of about 300 V or less.

An optical-to-electric conversion material forming the photoconductor layer 130 may have a finite electric conductivity that is greater than 0. Therefore, when an electric field is generated in the photoconductor layer 130 even in a state where radiation is not irradiated, a flow of an electric charge (e.g. a current) may occur.

The current flowing when no radiation is irradiated may be called dark current. The dark current is distinguished from a photocurrent that flows in response to electric charges generated by radiation. If there is dark current present when detecting the photocurrent, the dark current may generate noise.

One or more example embodiments may reduce the dark current, and, thus the noise generated thereby, via a variable voltage driving method in which the voltage generated by the variable voltage source 150 varies to reduce (or, alternatively, minimize) the dark current which is generated in the photoconductor layer 130 before radiation is irradiated onto the photoconductor layer 130.

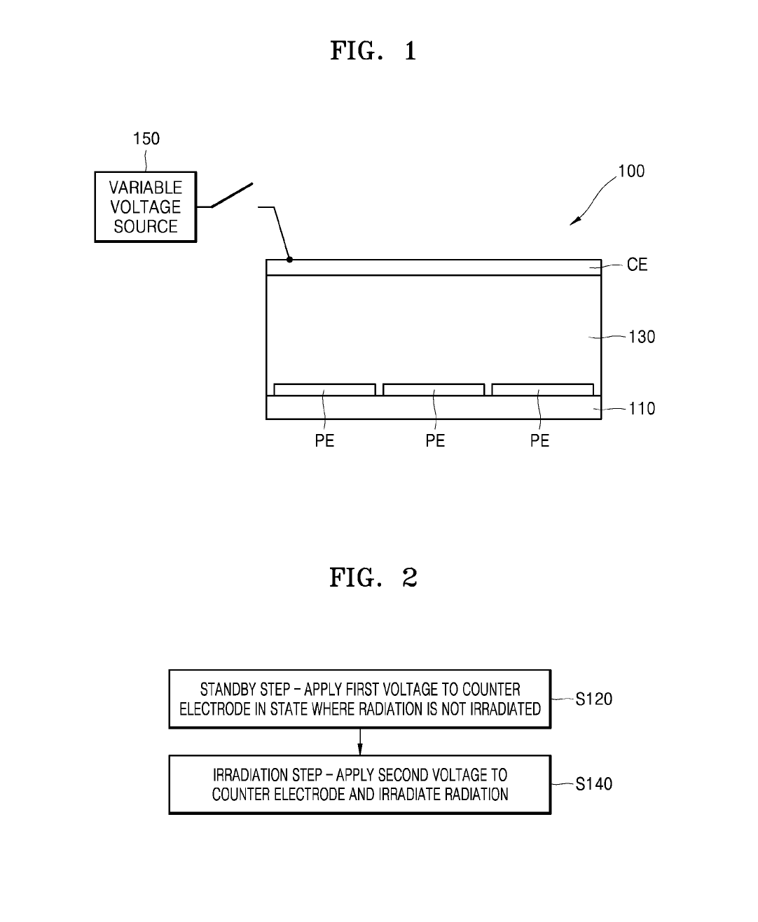

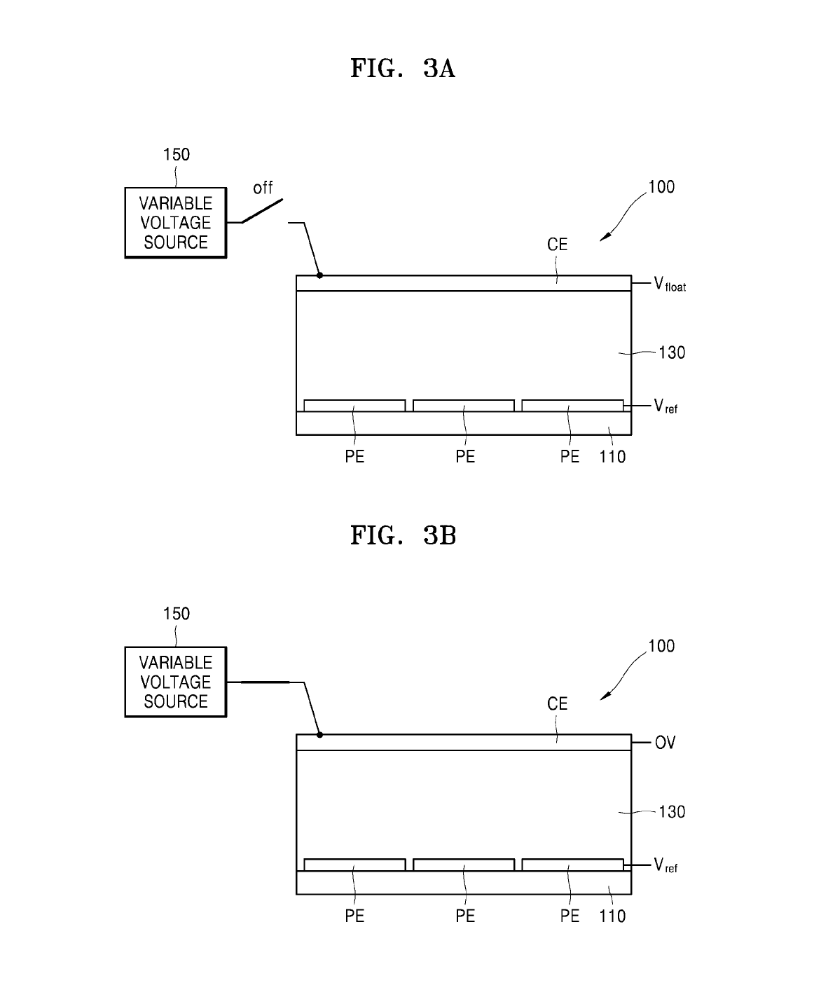

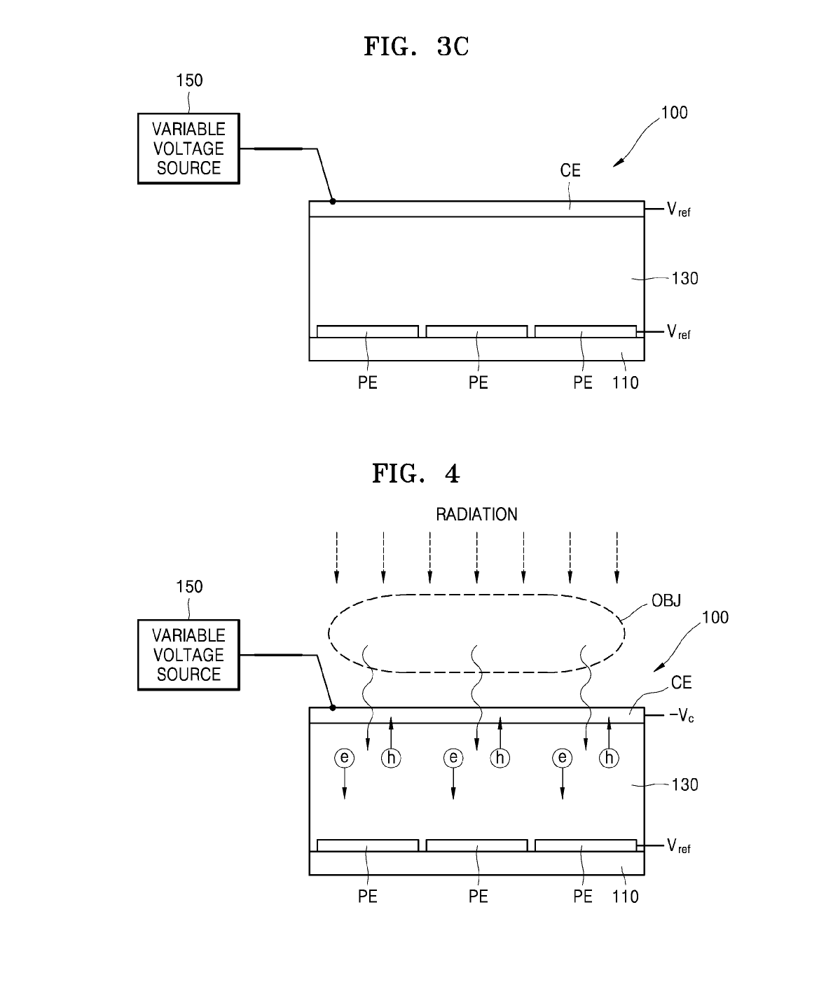

FIG. 2 is a flowchart for describing a method of driving a radiation detection apparatus according to an example embodiment. FIGS. 3A to 3C are diagrams illustrating examples of a first voltage which is applied to a counter electrode of a radiation detection apparatus in a standby operation of the flowchart of FIG. 2. FIG. 4 is a diagram for describing an operation in which a second voltage is applied to the counter electrode of the radiation detection apparatus, and when radiation is irradiated onto a photoconductor layer, a photocurrent is generated by the radiation, in an irradiation operation of the flowchart of FIG. 2.

Referring to FIGS. 2 to 4, a method of driving a radiation detection apparatus will be described by using the radiation detection apparatus 100 of FIG. 1.

In the method of driving a radiation detection apparatus according to an example embodiment, in operation S120, a control unit instructs the variable voltage source 150 to apply the first voltage to the counter electrode CE in a standby operation where radiation is not irradiated onto the photoconductor layer 130.

The first voltage is a voltage that is applied to the counter electrode CE to reduce (or, alternatively, minimize) an electric field generated in the photoconductor layer 130.

An optical-to-electric conversion material forming the photoconductor layer 130 is a material that has properties of a dielectric in a state where radiation is not irradiated, and when the radiation is irradiated, has properties of a conductor.

A resistivity of the photoconductor layer 130 is very large, but may not be infinite. Therefore, an electric conductivity of the photoconductor layer 130 may not completely 0 even before radiation is irradiated, and instead may have a value that is substantially greater than 0. For example, in HgI₂, electron mobility associated with electric conductivity is about 10⁻⁴ (cm ²/(V·s)), hole mobility associated with electric conductivity is about 10⁻⁶ (cm²/(V·s)), and resistivity is about 10¹³ (Ωcm).

Therefore, in a case where an electric field is generated in the photoconductor layer 130, even when radiation is not irradiated onto the photoconductor layer 130, a flow of an electric charges may occur in the photoconductor layer 130. The flow of the electric charges may generate a dark current, and may cause a noise component to be present in an image signal.

As discussed below, in one or more example embodiments, a control unit drives the radiation detection apparatus 100 by applying a variable voltage to reduce (or, alternatively, minimize) the dark current.

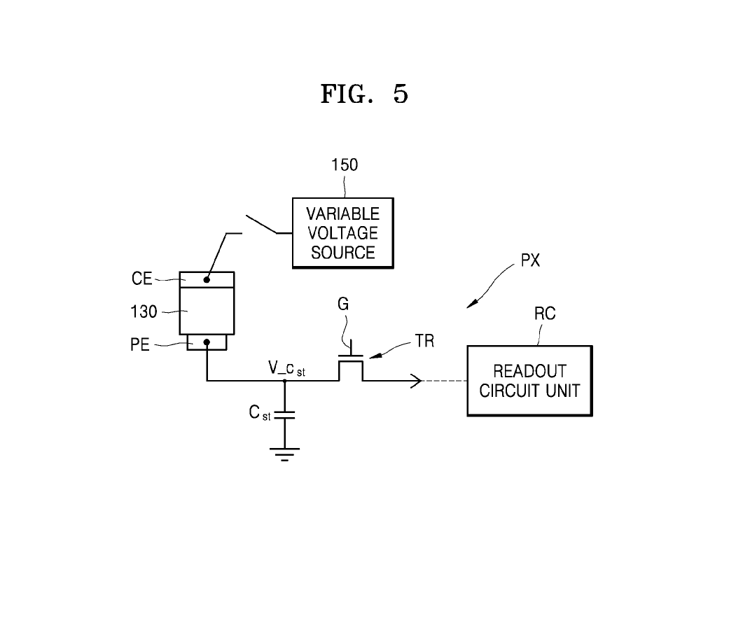

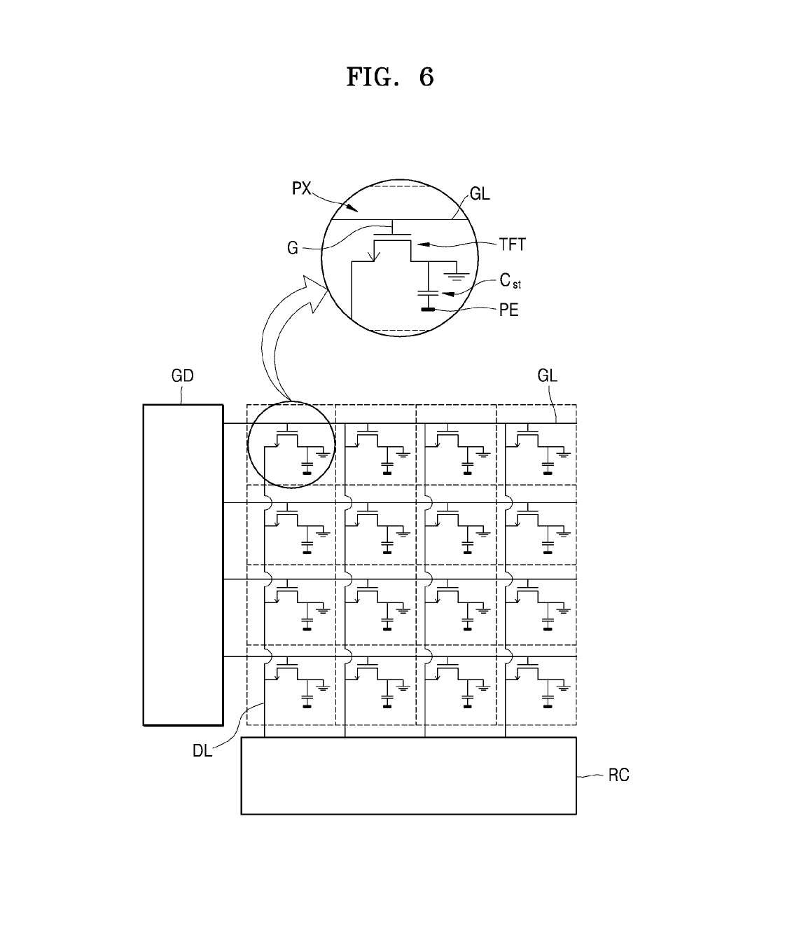

Referring to FIG. 3A, the first voltage may be a floating voltage V_{float}. That is, an off state in which an electrical connection between the variable voltage source 150 and the counter electrode CE is disconnected is formed. An electric potential V_{ref} generated in the pixel electrode PE is a value corresponding to a reference common voltage of a readout circuit unit (See FIGS. 5 and 6) connected to the array substrate 110, and is about 4 V to about 5 V. The floating voltage V_{float} applied to the counter electrode CE may be such that a certain electric potential is not maintained, and a substantially meaningful electric field is not generated between the counter electrode CE and the pixel electrode PE to which the electric potential V_{ref} is applied.

Referring to FIG. 3B, the first voltage is 0 V. The electric potential V_{ref} applied to the pixel electrode PE is a value close to 0, and an electric field is hardly generated in the photoconductor layer 130.

Referring to FIG. 3C, the first voltage may be the same value V_{ref} as an electric potential of the pixel electrode PE. In detail, a value which is substantially equivalent to the reference common voltage of the readout circuit unit connected to the pixel electrode PE may be applied to the counter electrode CE.

As discussed above, the floating voltage (FIG. 3A), 0 V (FIG. 3B), and the voltage Vref (FIG. 3C) may each be the first voltage applied to the counter electrode CE. However, example embodiments are not limited thereto.

For example, the control unit (not shown) may select the first voltage to reduce, prevent or minimize a dark current which is generated in a state where radiation is not irradiated onto the photoconductor layer 130, and, therefore, a value within a range in which an electric field is not generated in the photoconductor layer 130 or which is suitable for minimizing the electric field may be selected.

Referring back to FIG. 2, after the standby operation in which the first voltage is applied to the counter electrode CE, in operation S140, the control unit (not shown) may instruct the variable voltage source 150 to apply the second voltage to the counter electrode CE, and radiation is irradiated.

Referring to FIG. 4, the second voltage applied to the counter electrode CE may be −Vc. The voltage Vc may be determined based on an optical-to-electric conversion material forming the photoconductor layer 130, and a value of several hundreds V may be applied for driving a variable voltage. For example, Vc may be a value of about 300 V or less, or may be a value within a range of about 200 V to about 300 V. V_{ref} of several V is applied as the reference common voltage of the readout circuit unit, and an electric field is generated in the photoconductor layer 130 in a direction from the pixel electrode PE to the counter electrode CE.

Radiation irradiated onto an object OBJ passes through the object OBJ and is incident on the photoconductor layer 130. As the radiation is incident on the photoconductor layer 130, an electron-hole pair (e-h pair) may be generated in the photoconductor layer 130.

The electron-hole pair may be separated into an electron (e) and a hole (h) by the electric field generated in the photoconductor layer 130. The electron (e) may move to the pixel electrode PE, and the hole (h) may move to the counter electrode CE. An amount of electric charge (i.e., the number of generated electrons and holes) generated in the photoconductor layer 130 varies depending on a transmission amount of the radiation passing though the object OBJ, namely, an amount of electric charge detected through each of the plurality of pixel electrodes PE is changed. Based on such a difference, the inside of the object OBJ may be imaged.

FIG. 5 is a schematic diagram illustrating a transistor TR and a charging capacitor Cₛₜ, which are formed on an array substrate of a radiation detection apparatus according to an example embodiment, for one pixel PX.

Referring to FIG. 5, the pixel electrode PE is connected to the charging capacitor Cₛₜ. The charging capacitor Cₛₜ is used to collect electric charges, which are generated in the photoconductor layer 130, through the pixel electrode PE. The transistor TR acts as a switch for controlling an output (i.e., discharging) of electric charges stored in the charging capacitor Cₛₜ, to the outside. One electrode (for example, a source electrode) of the transistor TR is connected to the charging capacitor Cₛₜ, and the other electrode (for example, a drain electrode) is connected to a readout circuit unit RC.

Each of the pixel PXs may include one of the pixel electrodes PE, the charging capacitor Cₛₜ connected to the pixel electrode PE, and the transistor TR connected to the pixel electrode PE.

FIG. 6 is a circuit diagram illustrating an example of a circuit configuration of a radiation detection apparatus according to an example embodiment.

Referring to FIG. 6, a plurality of pixels PX are two-dimensionally arranged in a pixel array.

The pixel array may include a plurality of gate lines which extend in a first direction separated from each other at certain intervals, and a plurality of data lines DL which extend to intersect the plurality of gate lines GL.

The pixels PX may be provided in each of a plurality of regions formed by intersections of the plurality of gate lines GL and the plurality of data lines DL. Each of the pixels PX may include the pixel electrode PE, the charging capacitor Cₛₜ, and the transistor TR.

Further, a gate driver GD may be connected to the plurality of gate lines GL, and the readout circuit unit RC may be connected to the plurality of data lines DL.

When a gate voltage is applied to a gate G of the transistor TR via a corresponding gate line GL, a channel may be formed between the source electrode and drain electrode of the transistor TR, and electric charges stored in the charging capacitor Cₛₜ may be output through a corresponding data line DL and read by the readout circuit unit RC.

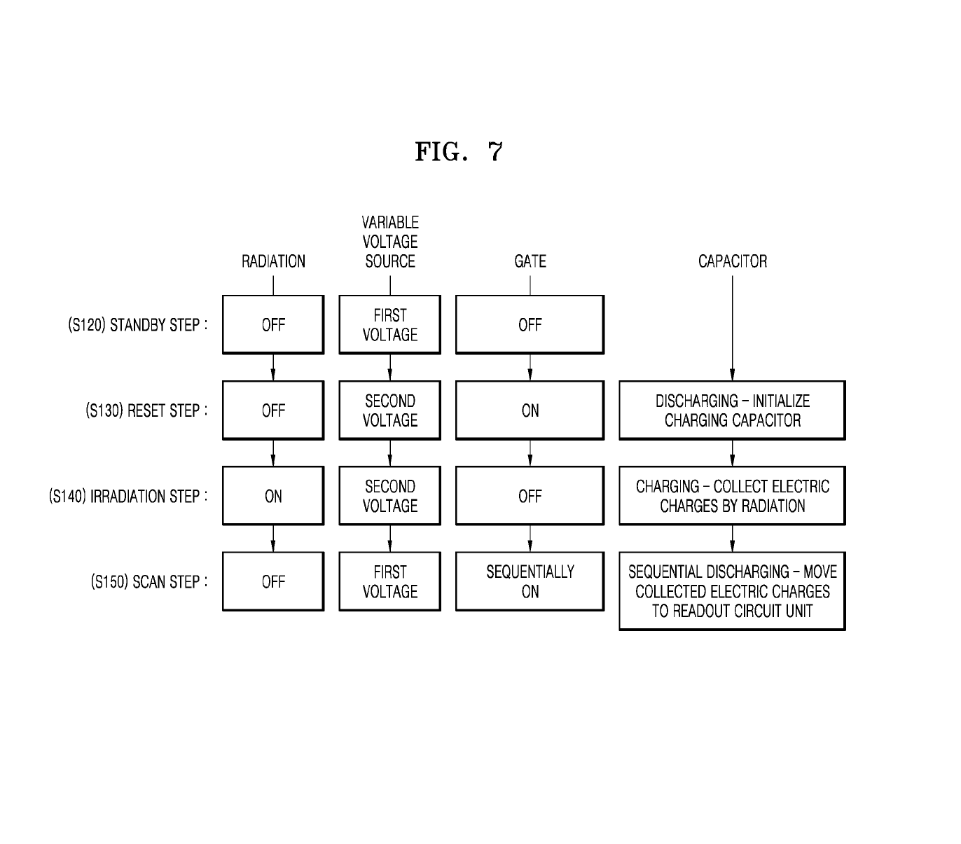

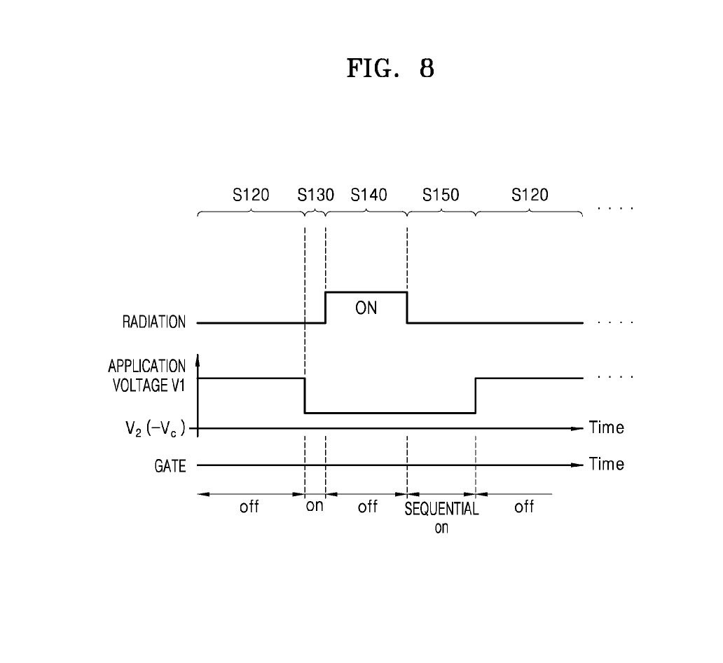

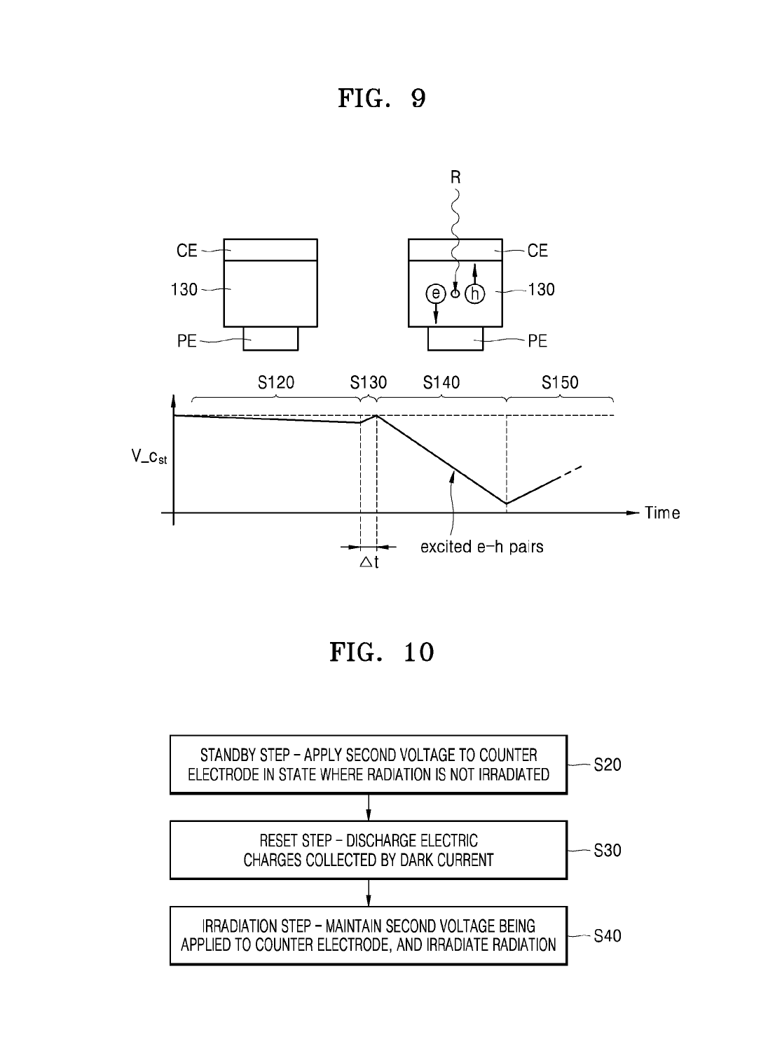

FIG. 7 is a block diagram illustrating in detail driving of a radiation source, a variable voltage source, a gate, and a charging capacitor in each operation of a method of driving a radiation detection apparatus according to an example embodiment. FIG. 8 is a graph showing driving of the radiation source, an application voltage, and a gate with time in each operation of a method of driving a radiation detection apparatus according to an example embodiment. FIG. 9 is a graph showing a change in a capacitor voltage in each operation of a method of driving a radiation detection apparatus according to an example embodiment.

The method of driving the radiation detection apparatus according to an example embodiment may include the standby operation S120, a reset operation S130, the irradiation operation S140, and a scan operation S150.

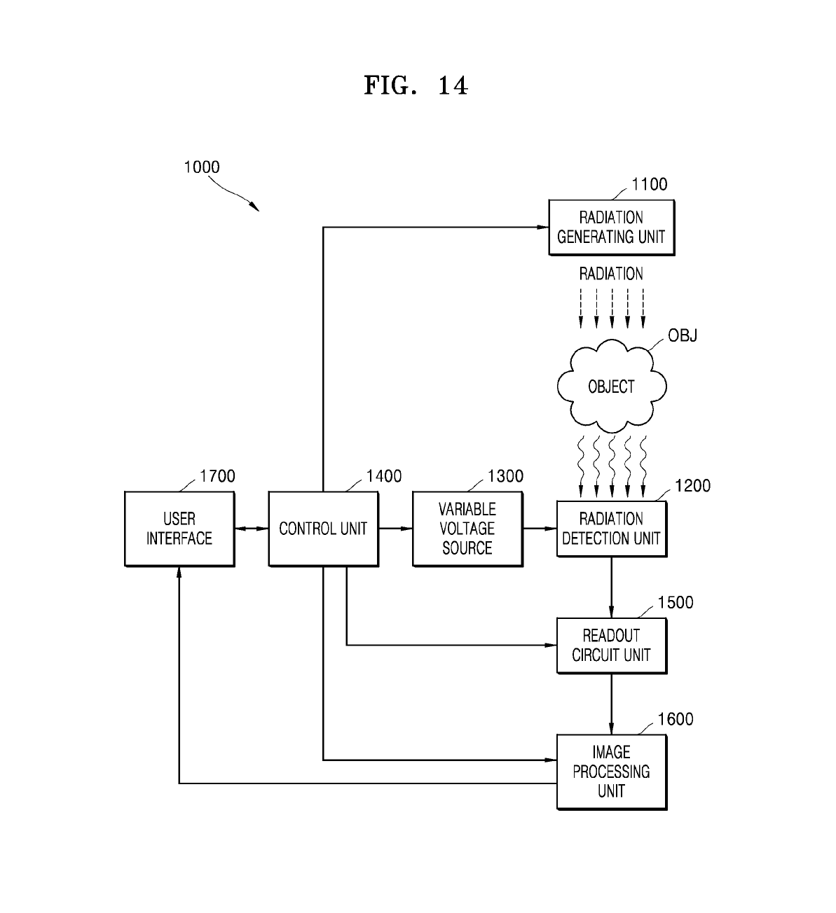

In the Standby operation S120 the control unit (see FIG. 14) may instruct a radiation generating unit (see FIG. 14) not to irradiate radiation onto the photoconductor layer 130, and further, may instruct the variable voltage source 150 to apply the first voltage V1 to the counter electrode CE.

During the Standby operation S120, the gate of the transistor TR connected to the pixel electrode PE is in an off state, namely, a state in which a gate voltage is not applied, and the charging capacitor Cₛₜ is in a chargeable state.

The first voltage applied by the variable voltage source 150 may be the floating voltage, 0 V, or a low voltage of 4 V to 5 V, and, thus, at most, a relatively small electric field is generated in the photoconductor layer 130.

When an electric field is generated in the photoconductor layer 130, electric charges may flow, and thus, the charging capacitor Cₛₜ may be charged. For example, when an electron moves to the pixel electrode PE in the photoconductor layer 130, as illustrated in FIG. 9, the charging capacitor Cₛₜ may be charged, and thus, a capacitor voltage V_{—Cst} may be lowered.

However, as illustrated in FIG. 9, in the method of driving the radiation detection apparatus according to an example embodiment, during the standby operation S120, the control unit (see FIG. 14) instructs the variable voltage source 150 to apply the first voltage V1 to the counter electrode CE. Therefore, an electric field is hardly generated in the photoconductor layer 130, and the capacitor voltage V_{—Cst} is hardly changed or is slightly changed.

In the Reset operation S130, the control unit (see FIG. 14) initializes the charging capacitor Cₛₜ by discharging electric charges stored in the charging capacitor Cₛₜ. During the Reset operation S130, the control unit may instruct the radiation generating unit not to irradiate radiation onto the photoconductor layer 130, and the variable voltage source 150 to apply the second voltage to the counter electrode CE. Also, the gate voltage is applied to the gate G of the transistor TR, and thus, a channel is formed between the source electrode and drain electrode of the transistor TR, and the electric charges stored in the charging capacitor Cₛₜ are discharged. As illustrated in FIG. 9, the capacitor voltage V_{—Cst} returns to an initial state as the charging capacitor Cₛₜ discharges.

In the method of driving the radiation detection apparatus according to an example embodiment, due to the control unit applying the first voltage V1 to the counter electrode CE to reduce the dark current during the standby operation S120, a time “Δt” taken to perform the Reset operation S130 is reduced.

In the method of driving the radiation detection apparatus according to some example embodiments, Reset operation S130 may be omitted all together.

During the Reset operation S130, the second voltage is applied to the counter electrode CE prior to a radiation irradiation timing, and after an electric field is generated in the photoconductor layer 130, radiation is irradiated onto an object, and electric charges generated by the radiation are collected. Therefore by performing the Reset operation S130 prior to the irradiation of radiation, a time for which the object is exposed to the radiation may be reduced.

In the Irradiation operation S140, the control unit may instruct the radiation generating unit to irradiate radiation onto the photoconductor layer 130 in a state where the variable voltage source 150 applies the second voltage V2 to the counter electrode CE. The second voltage V2 may be −Vc. The second voltage Vc may be a value which is determined based on a material of the photoconductor layer 130, and may have a value of about 300 V or less.

In irradiation operation S140, electric charges generated by radiation R irradiated onto the photoconductor layer 130 may be collected by the charging capacitor Cₛₜ connected to each of the plurality of pixel electrodes PE. An electron-hole pair generated in the photoconductor layer 130 is separated into an electron and a hole by an electric filed generated in the photoconductor layer 130, and the electron and the hole respectively move to the pixel electrode PE and the counter electrode CE. The gate of the charging capacitor Cₛₜ is turned off, and the electron moving to the pixel electrode PE is stored in the charging capacitor Cₛₜ.

As illustrated in FIG. 9, as the charging capacitor Cₛₜ is charged, the capacitor voltage V_{Cst} is lowered. During the irradiation operation S140, the change in the capacitor voltage V_{Cst} is caused by an electron (e)-hole (h) pair excited by the radiation R being irradiated, and is not caused by a dark current component.

Since an amount of radiation passing through the object OBJ varies depending on a region of the object OBJ through which radiation passes, the number of electron (e)-hole (h) pairs generated in the photoconductor layer 130 may also vary depending on a region of the photoconductor layer 130. Therefore, different amounts of electric charges may be stored in a plurality of the charging capacitors Cₛₜ respectively connected to the plurality of pixel electrodes PE.

In the Scan operation S150, the control unit instructs the transistors TR to sequentially provide the electric charges respectively stored in the plurality of charging capacitors Cₛₜ to the readout circuit unit, and the readout circuit unit may read the electric charges to generate a signal. During the scan operation S150, the control unit may instruct the radiation generating unit to stop the irradiation of radiation. Also, the control unit may instruct the variable voltage source 150 to apply the first voltage V1 to the counter electrode CE. The gate voltage is sequentially applied to the gates of the plurality of transistors TR, and thus, the electric charges stored in the charging capacitors Cₛₜ move to the readout circuit unit.

As illustrated in FIG. 9, as the electric charges stored in the charging capacitors Cₛₜ move to the readout circuit unit, the capacitor voltage V_{—Cst} increases again.

The control unit may perform operations S120 to S150, namely, the standby operation S120, reset operation S130, irradiation operation S140, and scan operation S150, repeatedly for continuously photographing images of a plurality of frames.

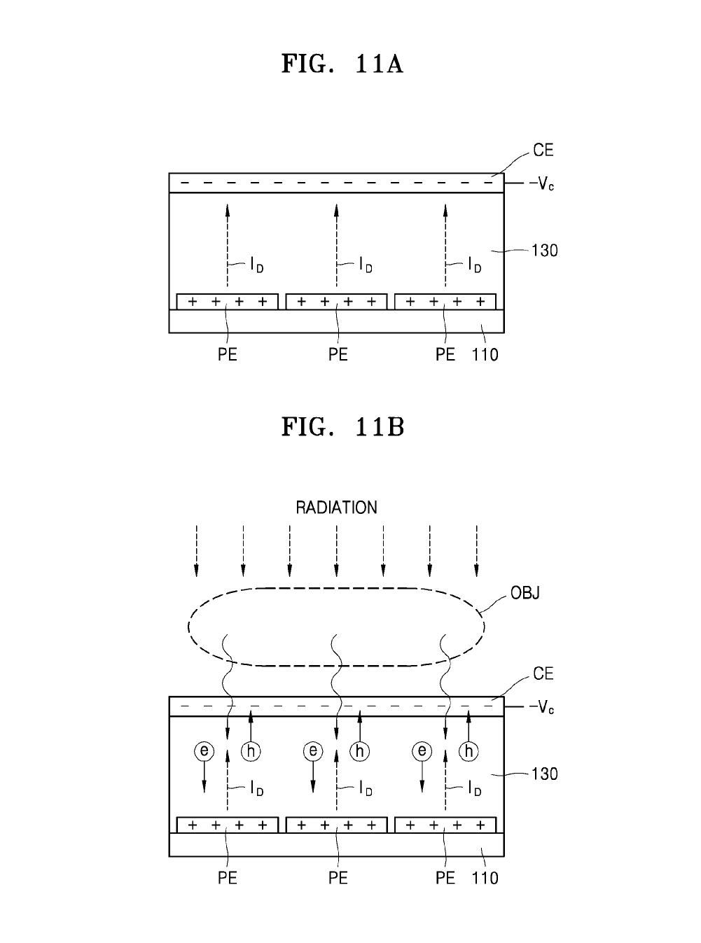

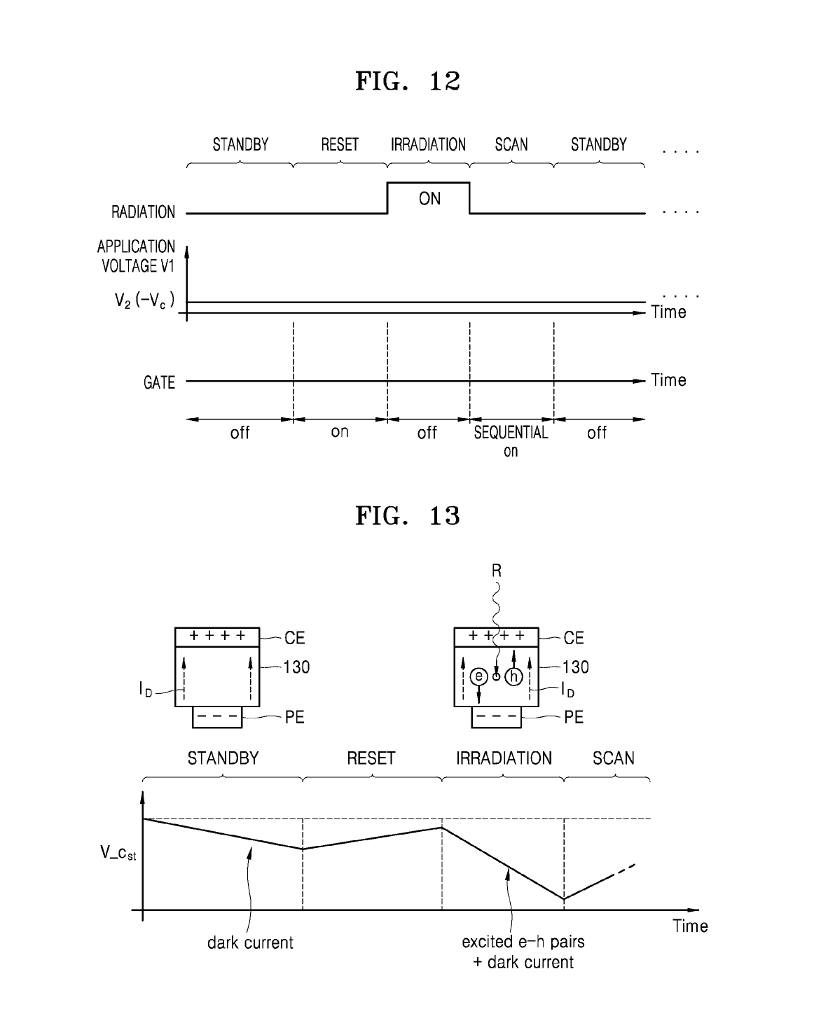

FIG. 10 is a flowchart for describing a method of driving a radiation detection apparatus according to a comparative example. FIGS. 11 A and 11 B are conceptual diagrams for describing an operation in which an electric charge caused by a dark current is detected along with an electric charge caused by radiation, in a method of driving a radiation detection apparatus according to a comparative example. FIG. 12 is a graph showing driving of radiation, an application voltage, and a gate with time in each step of a method of driving a radiation detection apparatus according to a comparative example. FIG. 13 is a graph showing a change in a capacitor voltage V_{—Cst} in each step of a method of driving a radiation detection apparatus according to a comparative example.

Referring to FIG. 10, the method of driving the radiation detection apparatus according to the comparative example, may include standby step S20, reset step S30, and irradiation step S40. In standby step S20 and reset step S30, a same second voltage V2 may be applied to a counter electrode of the radiation detection apparatus. That is, a voltage applied to the radiation detection apparatus maintains a constant value, and is not changed.

As described below with reference to FIGS. 11A and 11B, in the comparative example, noise may be caused by a dark current.

Referring to FIG. 11A, in standby step S20, since an electric field is generated in a photoconductor layer 130 even though radiation is not irradiated thereto, a flow of an electric charge occurs in the photoconductor layer 130 formed of an optical-to-electric conversion material having finite electric conductivity. The flow of the electric charge during the standby step S20 may be a dark current I_{D}.

As illustrated in FIG. 13, during the standby step S20, a charging capacitor Cst is charged through a pixel electrode PE by the dark current I_{D}, and thus, The capacitor voltage V_{Cst} changes.

Referring to FIG. 11 B, during an irradiation step S40, dark current I_{D} may exist in the photoconductor layer 130, when radiation is irradiated onto an object OBJ. When the radiation passing through the object OBJ is incident on the photoconductor layer 130, an electron (e)-hole (h) pair is generated, and is separated into an electron (e) and a hole (h) by an electric field which is generated in the photoconductor layer 130. The electron (e) moves to the pixel electrode PE, and the hole (h) moves to a counter electrode CE. Electric charges which are stored in the charging capacitor Cₛₜ through the pixel electrode PE include an electric charge, generated by the dark current I_{D}, and an electric charge generated by an electron-hole pair excited by the radiation. When detecting the radiation irradiated during the irradiation step, the electric charges due to by the dark current generated during the standby step S20 may cause noise.

In the method of driving the radiation detection apparatus according to the comparative example, in reset step S30, an operation in which electric charges collected by the dark current are discharged may be used to prevent the noise.

As illustrated in FIG. 13, during the reset step S130, the capacitor voltage V_{—Cst} is initialized by discharging the charging capacitor Cₛₜ. However, in comparison to FIG. 9, the time taken to perform the reset step S30 may be larger due to the increased amount of charges accumulated by the dark current during the standby step S20 in which the first voltage is not applied to the counter electrode CE.

After reset step S30, the irradiation step S40 may be performed. However, when the capacitor voltage V_{—Cst} is not completely restored to the original state in the reset step S30, the electric charges stored in the charging capacitor Cₛₜ may include electric charges generated by an electron-hole pair excited by the radiation R, and also electric charges generated by dark current I_{D}. The charging capacitors Cₛₜ are sequentially discharged in scan step, and when the electric charges generated by the dark current are read by the readout circuit unit, they may cause image noise.

In the method of driving the radiation detection apparatus according to an example embodiment, the reset step may be omitted or may be performed for a short time T, and therefore, any charges accumulated due to dark current may be removed prior to irradiating the photoconductor with radiation. Also, the operations may be repeated in continuous photographing, and thus, in the method of driving the radiation detection apparatus according to an example embodiment, the reset operation may be omitted, or a time taken in the reset operation may be considerably reduced.

FIG. 14 is a block diagram illustrating a schematic configuration of a radiation imaging apparatus 1000 according to an example embodiment.

The radiation imaging apparatus 1000 may include a radiation generating unit 1100 that irradiates radiation onto an object OBJ, a radiation detection unit 1200 that detects the radiation passing through the object OBJ, a variable voltage source 1300 that applies a variable voltage to the radiation detection unit 1200, and a control unit 1400 that controls the variable voltage source 1300.

The radiation imaging apparatus 1000 may further include a readout circuit unit 1500, which reads out an electrical signal from the radiation detection unit 1200 for each pixel, and an image processing unit 1600 that generates a radiation image of the object OBJ from the electrical signal which is read out by the readout circuit unit 1500 for each pixel. Also, the radiation imaging apparatus 1000 may further include a user interface 1700 that provides an interface between the radiation imaging apparatus 1000 and a user.

The radiation generating unit 1100 includes a radiation source that emits radiation. The radiation source may be, for example, a radiation tube including a cathode and an anode. An electromagnetic wave (for example, radiation such as an X-ray or a gamma ray) having a short wavelength may be generated by colliding an electron ray, which is emitted from the cathode of the radiation tube by vacuum discharging at a high speed, with the anode. The anode may use a metal material such as tungsten or molybdenum. A radiation spectrum may be changed depending on a material of the anode.

The radiation source emits radiation having certain energy, thereby enabling a single energy radiation image to be acquired. As another example, the radiation source irradiates a plurality of radiations having different energy a plurality of times, thereby enabling a multi-energy X-ray image (MEX) to be acquired. Also, the radiation generating unit 1100 may include a filter, which adjusts a radiation spectrum, and a collimator that controls an irradiation direction or an irradiation range of radiation.

The radiation detection unit 1200 receives radiation, which is irradiated from the radiation generating unit 1100 and passes through the object OBJ, to output an electrical signal. The radiation detection unit 1200 includes a plurality of pixel electrodes, a counter electrode that faces the plurality of pixel electrodes, and a photoconductor layer that is disposed between the plurality of pixel electrodes and the counter electrode. Also, the radiation detection unit 1200 includes a capacitor and a transistor that are connected to each of the plurality of pixel electrodes.

The radiation detection unit 1200, for example, may be disposed at an inner surface or a lower end of a rest (not shown) on which the object OBJ is located.

The variable voltage source 1300 applies a variable voltage to the counter electrode of the radiation detection unit 1200. For example, the control unit 1400 may control the variable voltage source 1300 to apply a first voltage to the counter electrode in a state where radiation is not irradiated onto the object OBJ, and to apply a second voltage, having an absolute value greater than the first voltage, to the counter electrode in a state where the radiation is irradiated onto the object OBJ.

The first voltage, which is applied to the radiation detection unit 1200 by the variable voltage source 1300, is used to reduce (or, alternatively, minimize) a dark current in a state where the radiation is not irradiated onto the object OBJ. Therefore, a time taken in a reset step (i.e., a time taken in initializing a capacitor voltage) performed before an irradiation step of applying the second voltage to the radiation detection unit 1200 and irradiating the radiation is reduced (or, alternatively, minimized), and it is possible to capture an image at a high speed.

The readout circuit unit 1500 is connected to each pixel of the radiation detection unit 1200, and reads out an electrical signal output from the radiation detection unit 1200 for each pixel.

The image processing unit 1600 may generate a radiation image, based on the electrical signal which is read out by the readout circuit unit 1500 for each pixel. For example, the image processing unit 1600 may estimate strength of the radiation, based on an intensity of the electrical signal detected from each pixel and thus substitute a certain image value into a pixel of a radiation image corresponding to each pixel, thereby generating a radiation image.

The radiation imaging apparatus 1000 may further include an image post-processing unit that performs post-processing on the radiation image processed by the image processing unit 1600. The image post-processing unit may correct a brightness, a color, a contrast, or a sharpness of the radiation image to correct the radiation image. As another example, the image post-processing unit may generate a three-dimensional stereoscopic radiation image by using a plurality of radiation images.

The above-described image processing unit 1600 has been described above as being included in the radiation imaging apparatus 1000. However, this is merely an example, and the example embodiments are not limited thereto. For example, the image processing unit 1600 may be provided in a workstation which is connected to the radiation imaging apparatus 1000 over a wired/wireless communication network.

The control unit 1400 may control the variable voltage source 1300 as described above, and moreover control an overall operation of the radiation imaging apparatus 1000. For example, the control unit 1400 may transfer a control signal, which is generated according to an input from a user, to the radiation generating unit 1100, the readout circuit unit 1500, or the image processing unit 1600 to control the overall operation of the radiation imaging apparatus 1000.

The control unit 1400 may include a processor and a memory (not shown).

The memory may be any device capable of storing data including magnetic storage, flash storage, etc. The processor may be any device capable of processing data including, for example, a microprocessor configured to carry out specific operations by performing arithmetical, logical, and input/output operations based on input data, or capable of executing instructions included in computer readable code stored in the memory. The processor may be a logic chip, for example, a central processing unit (CPU), a controller, or an application-specific integrated circuit (ASIC), that when, executing the instructions stored in the memory, configures the processor as a special purpose machine to perform the operations illustrated in FIG. 7 such that the processor is configured to reduce a dark current by reducing an electric field between the counter electrode CE and the pixel electrode PE. For example, the processor may instruct the variable voltage source 150, 1300 to apply a first voltage to the counter electrode CE in a state where radiation is not irradiated onto the object OBJ, and to apply a second voltage, having an absolute value greater than the first voltage, to the counter electrode CE in a state where the radiation is irradiated onto the object OBJ. Therefore, since the processor reduces the amount of dark current, the processor may improve the functioning of the control unit 1400 itself by reducing a time taken to initialize a capacitor voltage before irradiating the photoconductor with radiation, and, therefore, the processor may allow an imaging device to capture an image at a high speed.

In detail, the control unit 1400 may receive an instruction or a command of the user or various information through the user interface 1700, and control a certain operation of the radiation imaging apparatus 1000 by using the received instruction, command, or various information. Also, the control unit 1400 may control the certain operation of the radiation imaging apparatus 1000 according to a predetermined setting. For example, the control unit 1400 may transfer, to the radiation generating unit 1100, an amount of radiation to be irradiated or a control signal for irradiation start.

The user interface 1700 is an interface between a user and the radiation imaging apparatus 1000, and includes an input unit and an output unit. Information necessary for operating the radiation imaging apparatus 1000 is input through the user interface 1700, and an analyzed result may be output through the user interface 1700. For example, information, an instruction, or a command is input from the user through the input unit, and the input unit may include various buttons, a keyboard, a mouse, a trackball, a trackpad, a dome switch, a touch pad, a touch screen panel, various levers, a handle, or a stick. Also, the output unit may include a display unit and a sound output unit. The display unit may display a radiation image generated by the image processing unit 1600. The display unit may use various display panels such as a liquid crystal display (LCD) panel, an organic light-emitting diode (OLED) display panel, etc., and may also use a three-dimensional display panel. Also, the sound output unit may output a sound signal that notifies the start or end of capturing of a radiation image. The sound output unit may include a speaker and a buzzer.

The user interface 1700 has been described above as being included in the radiation imaging apparatus 1000. However, this is merely an example, and the example embodiments are not limited thereto. For example, the user interface 1700 may be provided in a separate workstation which transmits or receives data to or from the radiation imaging apparatus 1000 over the wired/wireless communication network.

The radiation imaging apparatus 1000 may further include a memory that stores a program executed in the control unit 1400, data necessary for control by the control unit 1400, or an image generated by the image processing unit 1600.

As described above, according to the one or more of the above example embodiments, the occurrence of a dark current is minimized in a standby step where radiation is not irradiated onto the photoconductor layer of the radiation detection apparatus.

In the method of driving the radiation detection apparatus according to an example embodiment, an initialization operation which is performed before radiation is irradiated is omitted or is performed for a short time, and thus, it is possible to drive the radiation detection apparatus at a high speed.

The radiation imaging apparatus according to an example embodiment acquires a good-quality radiation image at a high speed.

It should be understood that the example embodiments described therein should be considered in a descriptive sense only and not for purposes of limitation. Descriptions of features or aspects within each example embodiment should typically be considered as available for other similar features or aspects in other example embodiments.

While one or more example embodiments have been described with reference to the figures, it will be understood by those of ordinary skill in the art that various changes in form and details may be made therein without departing from the spirit and scope as defined by the following claims.

What is claimed is:

1. A method of driving a radiation detection apparatus, the radiation detection apparatus including a plurality of pixel electrodes, a counter electrode facing the plurality of pixel electrodes, and a photoconductor layer between the plurality of pixel electrodes and the counter electrode, the method comprising:
applying a first voltage to the counter electrode during a standby operation when no radiation is irradiated to the photoconductor layer; and
applying a second voltage to the counter electrode during an irradiation operation when radiation is irradiating onto the photoconductor layer, the second voltage having an absolute value greater than the first voltage.

2. The method of claim 1, wherein the first voltage is 0 V or a floating voltage.

3. The method of claim 1, wherein the plurality of pixel electrodes and the counter electrode have a substantially equivalent electric potential due to a value of the first voltage applied to the counter electrode.

4. The method of claim 1, wherein the radiation detection apparatus further comprises:
a readout circuit unit connected to the plurality of pixel electrodes, and wherein the first voltage is substantially equivalent to a reference common voltage of the readout circuit unit.

5. The method of claim 1, wherein an absolute value of the second voltage is 300 V or less.

6. The method of claim 1, wherein the radiation detection apparatus further includes a capacitor connected to each of the plurality of pixel electrodes, and the method further comprises:
discharging an electric charge stored in a capacitor after the standby operation and before the irradiating operation.

7. The method of claim 6, further comprising:
collecting, during the irradiation operation, electric charges generated by the radiation irradiated onto the photoconductor layer in the capacitor connected to each of the plurality of pixel electrodes.

8. The method of claim 6, further comprising:
sequentially discharging the capacitor so that the electric charges stored in the capacitor are read by the readout circuit unit.

9. A radiation detection apparatus comprising:
a substrate having a plurality of pixel electrodes arranged thereon;
a counter electrode facing the plurality of pixel electrodes;
a photoconductor layer between the plurality of pixel electrodes and the counter electrode, the photoconductor layer configured to generate an electric charge in response to radiation irradiated thereon;
a voltage source configured to apply a variable voltage to the counter electrode; and
a controller configured to,
instruct the voltage source to apply a first voltage to the counter electrode when the radiation is not irradiated onto the photoconductor layer, and
instruct the voltage source to apply a second voltage to the counter electrode when the radiation is irradiated onto the photoconductor layer, the second voltage having an absolute value greater than the first voltage.

10. The radiation detection apparatus of claim 9, wherein the controller is configured to set the first voltage to 0 V or a floating voltage.

11. The radiation detection apparatus of claim 9, wherein the controller is configured to set a value of the first voltage such that the plurality of pixel electrodes and the counter electrode have substantially equivalent electric potentials.

12. The radiation detection apparatus of claim 9, further comprising:
a plurality of capacitors connected to respective ones of the plurality of pixel electrodes;
a plurality of transistors configured to selectively discharge the plurality of capacitors; and
a readout circuit unit connected to the plurality of transistors.

13. The radiation detection apparatus of claim 13, wherein the controller is configured to set the first voltage to be substantially equivalent to a reference common voltage of the readout circuit unit.

14. The radiation detection apparatus of claim 9, wherein the photoconductor layer comprises:
a photoconductive material including one of HgI₂, HgO, PbI₂, CdTe, CdZnTe, PbO, PbO₂, CdS, and BiI₃.

15. The radiation detection apparatus of claim 9, wherein the controller is configured to set an absolute value of the second voltage to 300 V or less.

16. The radiation detection apparatus of claim 9, wherein the radiation detection apparatus is an X-ray detector or a gamma ray (y-ray) detector.

17. A radiation imaging apparatus comprising:
a radiation generator configured to irradiate radiation onto an object;
a radiation detector configured to output an electrical signal based on an amount of the radiation that passes through the object and irradiates onto the radiation detector, the radiation detector including a plurality of pixel electrodes, a counter electrode facing the plurality of pixel electrodes, and a photoconductor layer disposed between the plurality of pixel electrodes and the counter electrode;
a voltage source configured to apply a variable voltage to the counter electrode; and
a controller configured to instruct the voltage source to apply a first voltage to the counter electrode when the radiation is not irradiated onto the photoconductor layer and apply a second voltage to the counter electrode when the radiation is irradiated onto the photoconductor layer, the first voltage having an absolute value greater than the first voltage.

18. A method of reducing a dark current output by a photoconductive material, the method comprising:
applying a first voltage to the photoconductor such that an electrostatic field is not formed therein during a standby operation; and
applying a second voltage to the photoconductive material to form the electrostatic field during a collection operation in which x-rays are irradiated onto the photoconductive material after the standby operation, an absolute value of the second voltage being greater than an absolute value of the first voltage.

19. The method of claim 18, wherein the first voltage has a magnitude between 0 volts (V) and 5 volts (V), the second voltage has a magnitude less than 300 volts (V), and the photoconductive material is a material configured to operate at the second voltage.

20. The method of claim 18, wherein electric charges generated during the collection operation are stored in a capacitor, and the method further comprises:
discharging the electric charges stored in the capacitor during a reset operation between the standby operation and the irradiating operation.
